(19) United States
(12) Patent Application Publication
(10) Pub. No.: US 2018/0166418 A1
(43) Pub. Date: Jun. 14, 2018

(54) METHOD FOR PREPARING A WAFER LEVEL CHIP-ON-CHIP SEMICONDUCTOR STRUCTURE

(71) Applicant: NANYA TECHNOLOGY CORPORATION, New Taipei City (TW)

(72) Inventor: PO-CHUN LIN, CHANGHUA CITY (TW)

(21) Appl. No.: 15/853,522

(22) Filed: Dec. 22, 2017

Related U.S. Application Data
(62) Division of application No. 15/377,192, filed on Dec. 13, 2016.

(51) Int. Cl. H01L 25/065; H01L 21/56; H01L 25/00; H01L 23/00; H01L 23/538; H01L 23/31

(52) U.S. Cl. CPC H01L 25/0652; H01L 2225/06589; H01L 2224/48091; H01L 21/565; H01L 25/50; H01L 23/3128; H01L 25/0657; H01L 24/49; H01L 23/5384

(57) ABSTRACT

A method for preparing a wafer level chip-on-chip semiconductor structure. The semiconductor structure includes a first semiconductor device; at least one conductive member disposed over the first semiconductor device; a second semiconductor device disposed over the first semiconductor device; a molding member disposed over the first semiconductor device; and a redistribution layer (RDL) disposed over the second semiconductor device and the at least one conductive member. The molding member surrounds the second semiconductor device and the at least one conductive member. The molding member does not extend into an interface between the first semiconductor device and the second semiconductor device.

### PRIORITY CLAIM AND CROSS-REFERENCE

This patent application is a divisional application of and claims priority to U.S. patent application Ser. No. 15/377,192, filed on Dec. 13, 2016, which is incorporated by reference in its entirety.

### TECHNICAL FIELD

The present disclosure relates to a semiconductor structure and a method for preparing the same, and particularly relates to a wafer level chip-on-chip structure and a method for preparing the same.

### DISCUSSION OF THE BACKGROUND

Semiconductor devices are essential for many modern applications. With the advancement of electronic technology, semiconductor devices are becoming smaller in size while having greater functionality and greater amounts of integrated circuitry. Due to the miniaturized scale of semiconductor devices, the chip-on-chip structure is now widely used for manufacturing semiconductor devices. Numerous manufacturing steps are undertaken in the production of such semiconductor structure.

The manufacturing of semiconductor devices is becoming more complicated. The semiconductor device is assembled with a number of integrated components including various materials with differences in thermal properties. Since many components with different materials are combined, the complexity of the manufacturing operations of the semiconductor device is increased. Accordingly, there is a continuous need to improve the manufacturing process of semiconductor devices and address the above complexities.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor structure comprising a first semiconductor device; at least one conductive member disposed over the first semiconductor device; a second semiconductor device disposed over the first semiconductor device; a molding member disposed over the first semiconductor device, wherein the molding member surrounds the second semiconductor device and the at least one conductive member; and a redistribution layer (RDL) disposed over the second semiconductor device and the at least one conductive member.

In some embodiments, the second semiconductor device is disposed over the first semiconductor device substantially in the absence of a circuit substrate between the second semiconductor device and the first semiconductor device.

In some embodiments, the semiconductor structure further comprises a third semiconductor device disposed over the first semiconductor device substantially in the absence of a circuit substrate between the first semiconductor device and the third semiconductor device.

In some embodiments, the at least one conductive member is disposed over the first semiconductor device substantially in the to absence of soldering material between the at least one conductive member and the first semiconductor device.

In some embodiments, the semiconductor structure further comprises at least one conductive joint disposed over the redistribution layer.

In some embodiments, the first semiconductor device is a memory device.

In some embodiments, the second semiconductor device is a logic device, and the third semiconductor device is a memory device.

In some embodiments, the semiconductor structure comprises a heat dissipation path between the first semiconductor device and the second semiconductor device.

In some embodiments, the semiconductor structure comprises a heat dissipation path between the first semiconductor device and the third semiconductor device.

In some embodiments, a thermal dissipation resistance of the second semiconductor device and the first semiconductor device is smaller than a thermal dissipation resistance of the second semiconductor device and the redistribution layer.

In some embodiments, a thermal dissipation resistance of the third semiconductor device and the first semiconductor device is smaller than a thermal dissipation resistance of the third semiconductor device and the redistribution layer.

In some embodiments, the second semiconductor device and the third semiconductor device are disposed over the first semiconductor device via an adhesive.

In some embodiments, the molding member does not extend into an interface between the first semiconductor device and the second semiconductor device; similarly, the molding member does not extend into an interface between the first semiconductor device and the third semiconductor device.

Another aspect of the present disclosure provides a method for preparing a semiconductor structure, comprising: providing a first semiconductor device; forming at least one conductive member over the first semiconductor device; attaching a second semiconductor device over the first semiconductor device; forming a molding member over the first semiconductor device; and forming a redistribution layer (RDL) over the second semiconductor device and the at least one conductive member.

In some embodiments, the second semiconductor device and the third semiconductor device are attached over the first semiconductor device before the molding member is formed over the first semiconductor device; therefore, the molding member surrounds the second semiconductor device, the third semiconductor device, and the at least one conductive member. In some embodiments, the first semiconductor device serves as a carrier substrate of the second semiconductor device and the third semiconductor device during the formation of the molding member.

In some embodiments, the at least one conductive member is formed over the first semiconductor device substantially in the absence of soldering material between the at least one conductive member and the first semiconductor device.

In some embodiments, the second semiconductor device is attached to the first semiconductor device substantially in the absence of a circuit substrate between the second semiconductor device and the first semiconductor device.

In some embodiments, the method further comprises attaching a third semiconductor device to the first semiconductor device substantially in the absence of a circuit substrate between the first semiconductor device and the third semiconductor device.

In some embodiments, the method further comprises forming at least one conductive joint over the redistribution layer.

In some embodiments, the second semiconductor device is attached to the first semiconductor device via an adhesive.

In some embodiments, the second semiconductor device is attached to the first semiconductor device by a fusion bonding process.

In some embodiments, the second semiconductor device is attached to a front side of the first semiconductor device, and the method further comprises grinding a back side of the first semiconductor device.

In some embodiments, the semiconductor structure is in the absence of a circuit substrate and conductive bumps between the first semiconductor device and the second semiconductor device (and, if a third semiconductor device is present, between the first semiconductor device and the third semiconductor device), and the height of the semiconductor structure is smaller than a semiconductor structure having a corresponding intervening circuit substrate and conductive bumps. In other words, the semiconductor structure of the present disclosure can meet the miniaturized scale demand (small form factor) of the semiconductor device market.

In some embodiments, the second semiconductor device (and, if present, the third semiconductor device) is (are) disposed over the first semiconductor device substantially in the absence of an air gap having high thermal resistance between the second semiconductor device and the first semiconductor device; therefore, the thermal dissipation resistance between the second semiconductor device and the first semiconductor device is reduced, and there is a heat dissipation path between the first semiconductor device and the second semiconductor device. Consequently, the heat generated from the first semiconductor device or the second semiconductor device can be substantially dissipated to the surrounding environment through the heat dissipation path.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 is a cross-sectional view of a semiconductor structure in accordance with a comparative embodiment of the present disclosure.

FIG. 2 is a cross-sectional view of a semiconductor structure in accordance with some embodiments of the present disclosure.

FIG. 3 is a cross-sectional view of a semiconductor structure in accordance with some embodiments of the present disclosure.

FIG. 4 is a flow chart of a method for preparing a semiconductor structure in accordance with some embodiments of the present disclosure.

FIGS. 5 to 10 are schematic views of a process for preparing the semiconductor structure by the method of FIG. 4 in accordance with some embodiments of the present disclosure.

### DETAILED DESCRIPTION

The following description of the disclosure accompanies drawings, which are incorporated in and constitute a part of this specification, and illustrate embodiments of the disclosure, but the disclosure is not limited to the embodiments. In addition, the following embodiments can be properly integrated to complete another embodiment.

References to “one embodiment,” “an embodiment,” “exemplary embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

The present disclosure is directed to a wafer level chip-on-chip structure and a method for preparing the same. In order to make the present disclosure completely comprehensible, detailed steps and structures are provided in the following description. Obviously, implementation of the present disclosure does not limit special details known by persons skilled in the art. In addition, known structures and steps are not described in detail, so as not to unnecessarily limit the present disclosure. Preferred embodiments of the present disclosure will be described below in detail. However, in addition to the detailed description, the present disclosure may also be widely implemented in other embodiments. The scope of the present disclosure is not limited to the detailed description, and is defined by the claims.

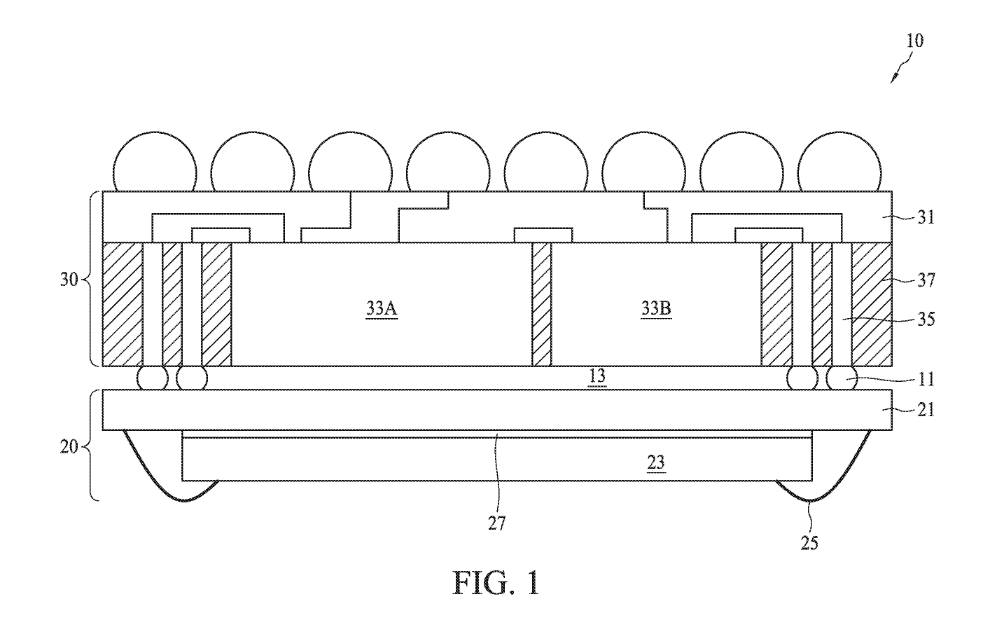

FIG. 1 is a cross-sectional view of a semiconductor structure 10 in accordance with a comparative embodiment of the present disclosure. The semiconductor structure 10 includes a first package 20 and a second package 30 bonded to the first package via a plurality of conductive bumps 11 to form a package on package (PoP) structure. The first package 20 includes a circuit substrate 21, a semiconductor chip 23 attached to the circuit substrate 21 via an adhesive 27, and a plurality of bonding wires 25 electrically connecting the semiconductor chip 23 and the circuit substrate 21. The second package 30 includes a redistribution layer 31, a semiconductor chip 33A and a semiconductor chip 33B on the redistribution layer 31, a plurality of conductive vias 35 electrically connecting the conductive terminals of the redistribution layer 31 to the conductive bumps 11, and a molding member 37 encapsulating the semiconductor chip 33A and the semiconductor chip 33B on the redistribution layer 31.

In preparing the PoP semiconductor structure 10, the semiconductor chip (die) 23 is disposed over the circuit substrate 21 via the adhesive 27 to become a first package 20; the semiconductor chip 33A and the semiconductor chip 33B are disposed on a carrier substrate and encapsulated by the molding member 37, the redistribution layer 31 is then formed on the molded semiconductor chip 33A and semiconductor chip 33B, and the carrier substrate is removed; and then the first package 20 is attached to the second package 30 to form the package on package (PoP) semiconductor structure 10 via the conductive bumps 11. The height of such PoP semiconductor structure 10 is not easily further reduced to meet the miniaturized scale demand of the semiconductor device market. In addition, the air gap 13 formed by the conductive bumps 11 between the first package 20 and the second package 30 in the PoP semiconductor structure 10 has a relatively poor thermal dissipation ability, and the heat dissipation becomes a serious challenge as the semiconductor devices become smaller in size while having greater functionality and greater amounts of integrated circuitry. Furthermore, some of the PoP structure may need a double-sided redistribution layer (RDL), which is relatively expensive and has relatively poor process efficiency.

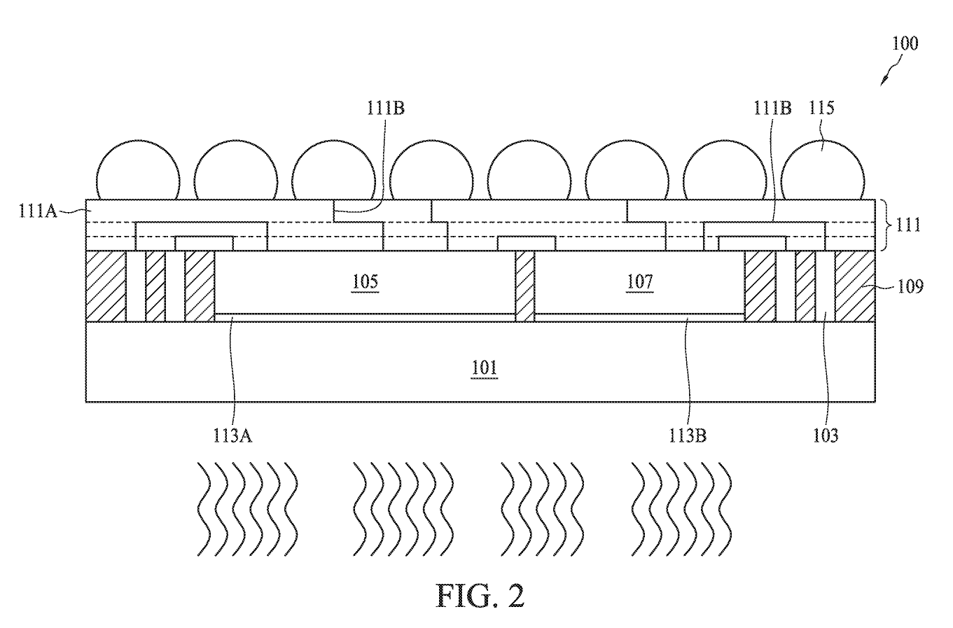

FIG. 2 is a cross-sectional view of a semiconductor structure 100 in accordance with some embodiments of the present disclosure. In some embodiments, the semiconductor structure 100 comprises a first semiconductor device 101; one or more conductive members 103 disposed over the first semiconductor device 101; a second semiconductor device 105 and a third semiconductor device 107 disposed over the first semiconductor device 101; a molding member 109 disposed over the first semiconductor device 101; and a redistribution layer (RDL) 111 disposed over the second semiconductor device 105, the third semiconductor device 107, and the conductive member 103. In some embodiments, the molding member 109 surrounds the second semiconductor device 105, the third semiconductor device 107, and the conductive member 103. In some embodiments, the first semiconductor device 101 may include a redistribution layer for electrically connecting the first semiconductor device 101 to the second semiconductor device 105, the third semiconductor device 107 and the conductive member 103.

In some embodiments, the first semiconductor device 101 is a memory chip such as a DRAM (Dynamic Random Access Memory) chip, the second semiconductor device 105 is a logic chip such as a CPU (Central Processing Unit)/GPU (Graphics Processing Unit) chip, and the third semiconductor device 107 is a memory chip such as a cache chip.

In some embodiments, the second semiconductor device 105 is disposed over the first semiconductor device 101 via an adhesive 113A or by a fusion bonding process; in other words, the second semiconductor device 105 is disposed over the first semiconductor device 101 substantially in the absence of the molding member 109 between the second semiconductor device 105 and the first semiconductor device 101.

In some embodiments, the third semiconductor device 107 is disposed over the first semiconductor device 101 via an adhesive 113B or by a fusion bonding process; in other words, the third semiconductor device 107 is disposed over the first semiconductor device 101 substantially in the absence of the molding member 109 between the first semiconductor device 101 and the third semiconductor device 107.

Details of the fusion bonding process are available in the article (An Overview of Patterned Metal/Dielectric Surface Bonding: Mechanism, Alignment and Characterization, J. Electrochem. Soc. 1011 volume 158, issue 6, P81-P86), the entirety of which is incorporated herein by reference and will not be repeated.

In some embodiments, the molding member 109 can be a single-layer film or a composite stack. In some embodiments, the molding member 109 includes various materials, such as molding compound, molding underfill, epoxy, resin, or the like. In some embodiments, the molding member 109 has a high thermal conductivity, a low moisture absorption rate and a high flexural strength.

In some embodiments, the adhesive 113A and the adhesive 113B are thermally conductive or have a thermal conductivity of between approximately 0.01 and 100 W/(m·K). In some embodiments, the adhesive 113A and the adhesive 113B includes aluminum, silver, carbon, or other particle with thermal conductivity higher than 25 W/(m·K).

In some embodiments, the second semiconductor device 105, the third semiconductor device 107, and the conductive member 103 are surrounded by the molding member 109. In some embodiments, the conductive member 103 includes conductive material such as copper, aluminum, or silver. In some embodiments, the conductive member 103 is extended through the molding member 109. In some embodiments, the conductive member 103 is extended between a terminal of the first semiconductor device 101 and a terminal of the redistribution layer 111. In some embodiments, the conductive member 103 is a through molding via (TMV). In some embodiments, the conductive member 103 is disposed over the first semiconductor device 101 substantially in the absence of soldering material between the conductive member 103 and the first semiconductor device 101.

In some embodiments, the redistribution layer 111 comprises a dielectric stack 111A and several conductive lines 111B disposed in the dielectric stack 111A. The conductive line 111B electrically connects a first conductive terminal on an upper side and a second conductive terminal on a bottom side. The conductive line 111B is also used to form an electrical connection among conductive member 103, the second semiconductor device 105, and the third semiconductor device 107. In some embodiments, the conductive line 111B is made of copper, gold, silver, nickel, solder, tin, lead, tungsten, aluminum, titanium, palladium or alloys thereof.

In some embodiments, the semiconductor structure 100 further comprises at least one conductive joint 115 disposed over the redistribution layer 111. In some embodiments, the conductive joint 115 is disposed on the upper side of the redistribution layer 111, while the second semiconductor die 105 and the third semiconductor die 107 are disposed on the bottom side of the redistribution layer 111. In some embodiments, the conductive joint 115 is a conductive bump, which includes conductive material such as solder, copper, nickel, or gold. In some embodiments, the conductive joint 115 is a solder ball, a ball grid array (BGA) ball, a controlled collapse chip connection (C4) bump, a microbump, a pillar or the like. In some embodiments, the conductive joint 115 has a spherical, hemispherical or cylindrical shape.

Comparing the semiconductor structure 10 in FIG. 1 with the semiconductor structure 100 in FIG. 2, the semiconductor structure 10 in FIG. 1 has additional elements (the circuit substrate 21 and the conductive bumps 11), while the semiconductor structure 100 in FIG. 2 is in the absence of such elements. Consequently, the height of the semiconductor structure 100 in FIG. 2 is less than the height of the semiconductor structure 100 in FIG. 1. In other words, the semiconductor structure 100 in FIG. 2 can meet the miniaturized scale demand (small form factor) of the semiconductor device market.

In addition, referring to FIG. 2, the second semiconductor device 105 is disposed over the first semiconductor device 101 substantially in the absence of an air gap having high thermal resistance between the second semiconductor device 105 and the first semiconductor device 101; therefore, the thermal dissipation resistance between the second semiconductor device 105 and the first semiconductor device 101 is reduced, and there is a heat dissipation path between the first semiconductor device 101 and the second semiconductor device 105. Consequently, the heat generated from the first semiconductor device 101 or the second semiconductor device 105 can be substantially dissipated to the surrounding environment through the heat dissipation path with a smaller thermal dissipation resistance.

Similarly, referring to FIG. 2, the third semiconductor device 107 is disposed over the first semiconductor device 101 substantially in the absence of an air gap having high thermal resistance between the first semiconductor device 101 and the third semiconductor device 107; therefore, the thermal dissipation resistance between the third semiconductor device 107 and the first semiconductor device 101 is reduced, and there is a heat dissipation path between the first semiconductor device 101 and the third semiconductor device 107. Consequently, the heat generated from the first semiconductor device 101 or the third semiconductor device 107 can be substantially dissipated to the surrounding environment through the heat dissipation path with a smaller thermal dissipation resistance.

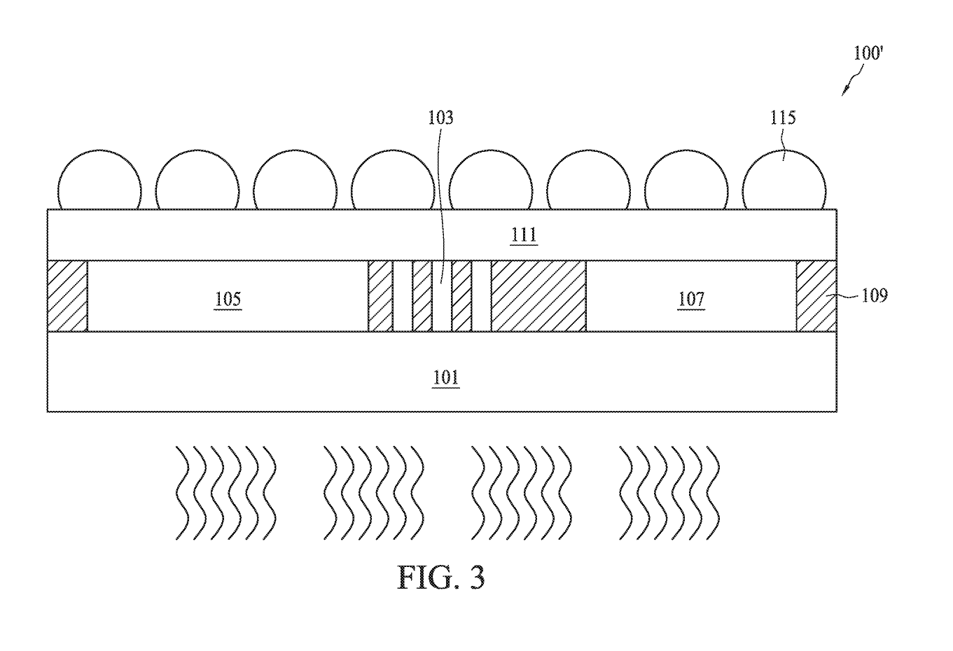

FIG. 3 is a cross-sectional view of a semiconductor structure 100′ in accordance with some embodiments of the present disclosure. The semiconductor structure 100′ shown in FIG. 3 is substantially the same as the semiconductor structure 100 shown in FIG. 2, except for the position of the conductive member 103. In FIG. 2, the conductive member 103 is disposed in a peripheral region of the semiconductor structure 100, while the conductive member 103 in FIG. 3 is disposed in a central region of the semiconductor structure 100′.

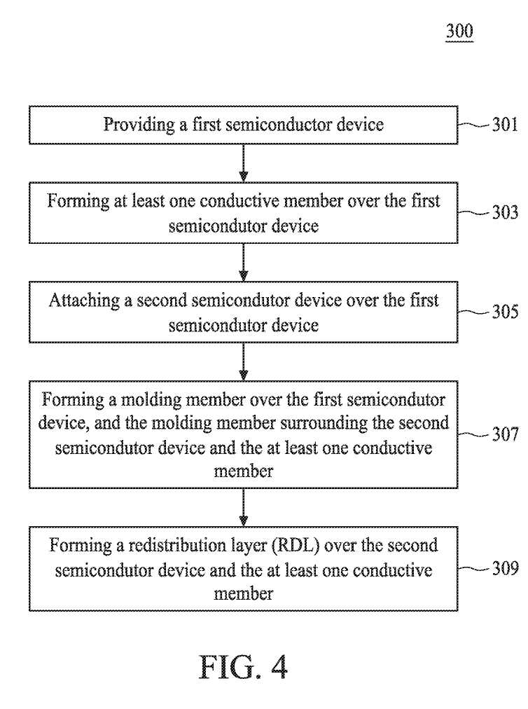

In the present disclosure, a method for preparing a semiconductor structure is also disclosed. In some embodiments, the semiconductor structure can be formed by a method 300 as illustrated in FIG. 4. The method 400 includes a number of operations and the description and illustration are not deemed as a limitation of the sequence of the operations. The method 300 includes a number of steps (301, 303, 305, 307, and 309).

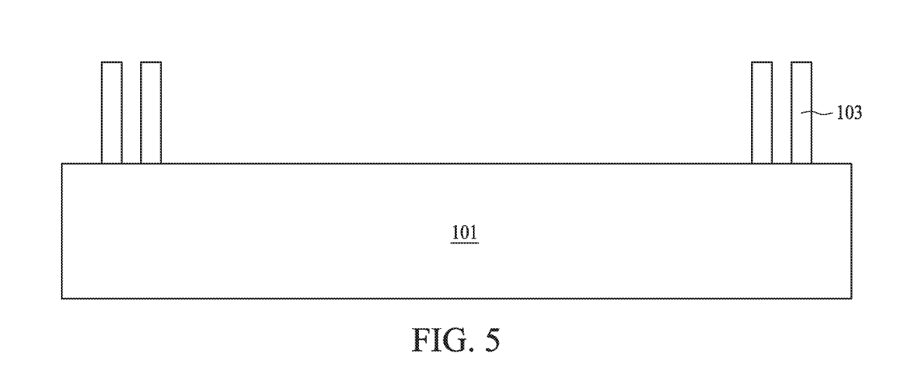

In step 301, a first semiconductor device 101 is provided as shown in FIG. 5. In some embodiments, the first semiconductor device 101 is a memory device such as a DRAM chip or a DRAM wafer.

In step 303, several conductive members 103 are formed over the first semiconductor device 101 as shown in FIG. 5. In some embodiments, the conductive member 103 is formed by lithographic process and plating process or any other suitable process substantially in the absence of soldering material between the conductive member 103 and the first semiconductor device 101.

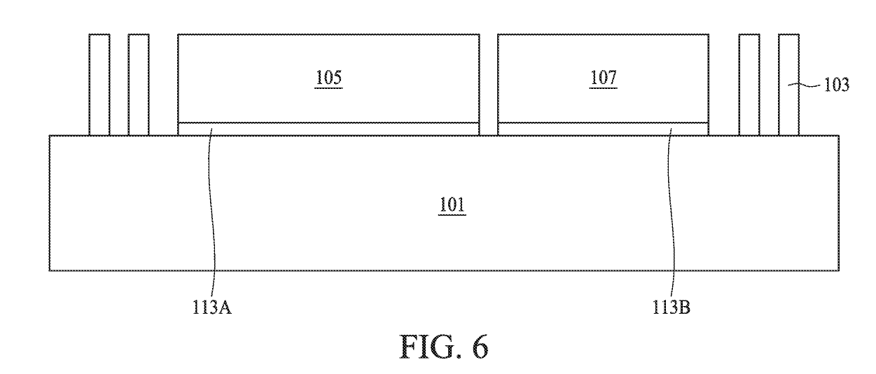

In step 305, a second semiconductor device 105 and a third semiconductor device 107 are attached over the first semiconductor device 101 as shown in FIG. 6. In some embodiments, the second semiconductor device 105 is disposed over the first semiconductor device 101 via an adhesive 113A or by a fusion bonding process, substantially in the absence of a circuit substrate between the second semiconductor device 105 and the first semiconductor device 101. Similarly, the third semiconductor device 107 is disposed over the first semiconductor device 101 via an adhesive 113B or by a fusion bonding process, substantially in the absence of a circuit substrate between the third semiconductor device 107 and the first semiconductor device 101.

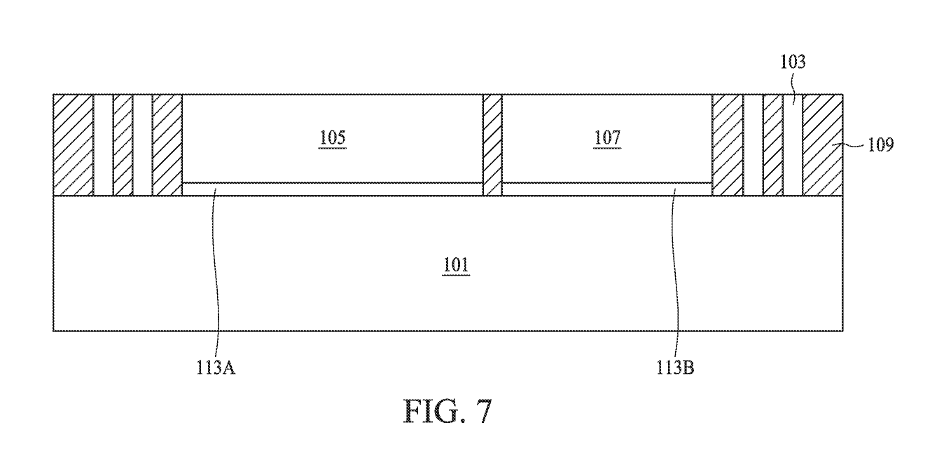

In step 307, a molding member 109 is formed over the first semiconductor device 101 as shown in FIG. 7. In some embodiments, the second semiconductor device 105 and the third semiconductor device 107 are attached over the first semiconductor device 101 before the molding member 109 is formed over the first semiconductor device 101; therefore, the molding member 109 surrounds the second semiconductor device 105, the third semiconductor device 107, and the conductive member 103. In some embodiments, the first semiconductor device 101 serves as a carrier substrate of the second semiconductor device 105 and the third semiconductor device 107 during the formation of the molding member 109.

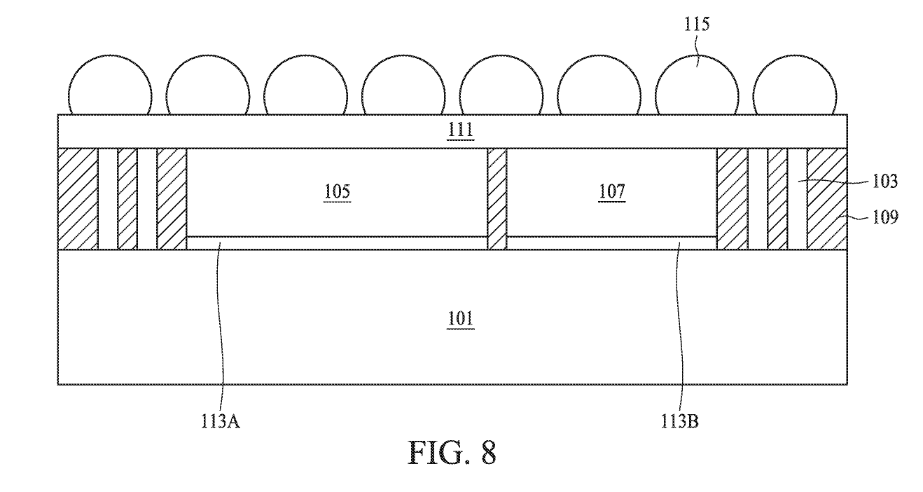

In step 309, a redistribution layer 111 is formed over the second semiconductor device 105, the third semiconductor device 107, and the conductive member 103, as shown in FIG. 8. In some embodiments, the redistribution layer 111 is formed by deposition, lithographic and etching processes. In addition, several conductive joints 115 are formed over the redistribution layer 111. In some embodiments, the redistribution layer 111 is formed after the formation of the molding member 109.

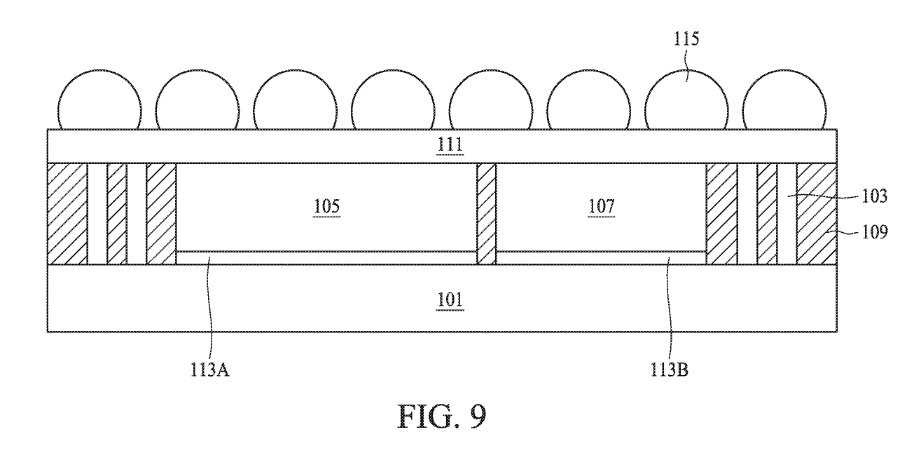

Referring to FIG. 9, the first semiconductor device 101 is made thinner by performing a grinding process on the back side of the first semiconductor device 101, wherein the second semiconductor device 105 and the third semiconductor device 107 are disposed on the front side of the first semiconductor device 101.

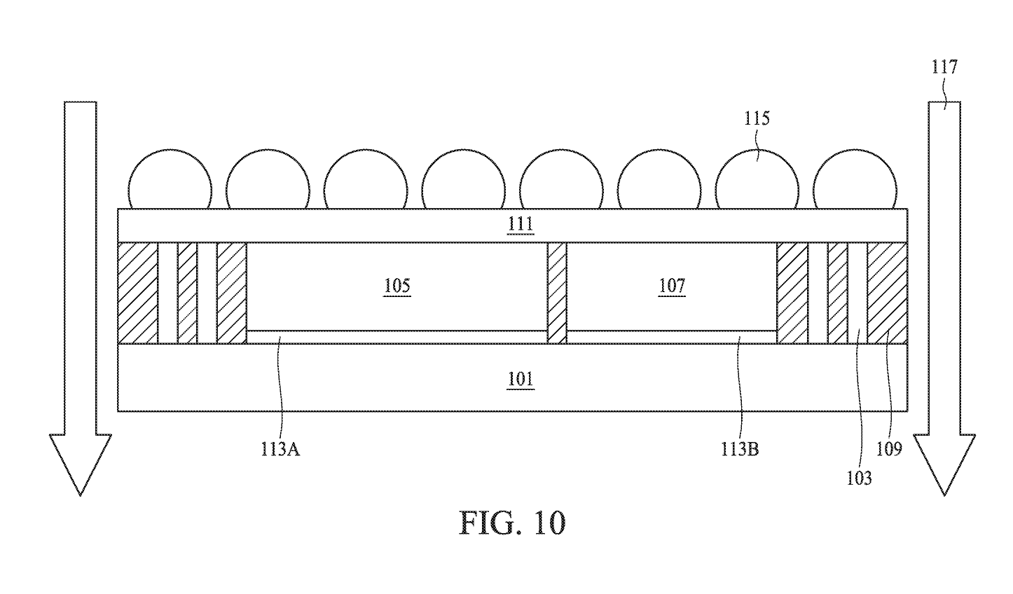

Referring to FIG. 10, the wafer is cut into separated semiconductor packages. In some embodiments, the wafer is separated through a die cutting or singulation process in which, typically, a singulation tool 117 such as a mechanical or laser saw is used to cut through the substrate between individual chips or dies. In some embodiments, the laser sawing uses an Argon (Ar) based ion laser beam tool.

One aspect of the present disclosure provides a semiconductor structure. The semiconductor structure includes a first semiconductor device; at least one conductive member disposed over the first semiconductor device; a second semiconductor device disposed over the first semiconductor device; a molding member disposed over the first semiconductor device; and a redistribution layer (RDL) disposed over the second semiconductor device and the at least one conductive member; wherein the molding member surrounds the second semiconductor device and the at least one conductive member.

Another aspect of the present disclosure provides a method for preparing a semiconductor structure. The method includes providing a first semiconductor device; forming at least one conductive member over the first semiconductor device; attaching a second semiconductor device over the first semiconductor device; forming a molding member over the first semiconductor device, wherein the molding member surrounds the second semiconductor device and the at least one conductive member; and forming a redistribution layer (RDL) over the second semiconductor device and the at least one conductive member.

In some embodiments, the second semiconductor device is attached to the first semiconductor device before the molding member is formed over the first semiconductor device; therefore, the molding member surrounds the second semiconductor device and the at least one conductive member. In some embodiments, the first semiconductor device serves as a carrier substrate of the second semiconductor device during the formation of the molding member.

In some embodiments, the semiconductor structure is in the absence of a circuit substrate and conductive bumps between the first semiconductor device and the second semiconductor device (and, if a third semiconductor device is present, between the first semiconductor device and the third semiconductor device); therefore, the height of the semiconductor structure is less than the height of a semiconductor structure having a corresponding intervening circuit substrate and conductive bumps. In other words, the semiconductor structure of the present disclosure can meet the miniaturized scale demand (small form factor) of the semiconductor device market.

In some embodiments, the second semiconductor device (and, if present, the third semiconductor device) is (are) disposed over the first semiconductor device substantially in the absence of an air gap having high thermal resistance between the second semiconductor device and the first semiconductor device; therefore, the thermal dissipation resistance between the second semiconductor device and the first semiconductor device is reduced, and there is a heat dissipation path between the first semiconductor device and the second semiconductor device. Consequently, the heat generated from the first semiconductor device or the second semiconductor device can be substantially dissipated to the surrounding environment through the heat dissipation path.

Although the present disclosure and its advantages have been described in detail, it should be understood that various changes, substitutions and alterations can be made herein without departing from the spirit and scope of the disclosure as defined by the appended claims. For example, many of the processes discussed above can be implemented through different methods, replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed is:

1. A method for preparing a semiconductor structure, comprising:
providing a first semiconductor device;
forming at least one conductive member over the first semiconductor device;
attaching a second semiconductor device over the first semiconductor device;
forming a molding member over the first semiconductor device, wherein the molding member surrounds the second semiconductor device and the at least one conductive member; and
forming a redistribution layer (RDL) over the second semiconductor device and the at least one conductive member.

2. The method of claim 1, wherein the second semiconductor device is attached to the first semiconductor device substantially in the absence of a circuit substrate between the second semiconductor device and the first semiconductor device.

3. The method of claim 1, further comprising: attaching a third semiconductor device to the first semiconductor device substantially in the absence of a circuit substrate between the first semiconductor device and the third semiconductor device.

4. The method of claim 1, wherein the at least one conductive member is attached to the first semiconductor device substantially in the absence of soldering material between the at least one conductive member and the first semiconductor device.

5. The method of claim 1, further comprising forming at least one conductive joint over the redistribution layer.

6. The method of claim 1, wherein the second semiconductor device is attached to the first semiconductor device via an adhesive.

7. The method of claim 1, wherein the second semiconductor device is attached to the first semiconductor device by a fusion bonding process.

8. The method of claim 1, wherein the second semiconductor device is attached to a front side of the first semiconductor device, and the method further comprises grinding a back side of the first semiconductor device.
